(19) United States
(12) Patent Application Publication
(10) Pub. No.: US 2016/0366792 A1
(43) Pub. Date: Dec. 15, 2016

(54) MULTIPLE TANK COOLING SYSTEM

(71) Applicant: Hewlett Packard Enterprise Development LP, Houston, TX (US)

(72) Inventors: Kelly K SMITH, Spring, TX (US); Richard A BARGERHUFF, Spring, TX (US); Rachel Nicole POLLOCK, Houston, TX (US); Kapil Rao GANTA PAPA RAO BALA, Houston, TX (US)

(21) Appl. No.: 15/120,515

(22) PCT Filed: May 28, 2014
(86) PCT No.: PCT/US2014/039837

§ 371 Date: Aug. 19, 2016

(51) Int. Cl. H05K 7/20; G05D 7/06

(52) U.S. Cl. CPC H05K 7/20781; G05D 7/0635; H05K 7/20836

(57) ABSTRACT

Examples herein disclose a multiple tier cooling structure. The multiple tier cooling structure includes multiple tanks, multiple inlets, and multiple outlets. Each of the multiple tanks are on a respective tier, each of the multiple inlets are located on a first side at each tank to direct a cooling fluid from the first side of each tank to a second side. Each of the multiple outlets are located on the second side at each tank to direct an expulsion of the cooling fluid from each tank.

### BACKGROUND

Cooling fluids flow through or around components to prevent overheating of the components. The heat produced by the components may be transferred to the cooling fluid to regulate the temperature of the components.

### BRIEF DESCRIPTION OF THE DRAWINGS

In the accompanying drawings, like numerals refer to like components or blocks. The following detailed description references the drawings, wherein:

FIG. 1 is a block diagram of an example multiple tier cooling structure including multiple tanks on each respective tier, multiple inlets to guide allow of cooling fluid, and multiple outlets to expel the cooling fluid from each tank;

FIG. 2A is a block diagram of example multiple tanks on one tier from a front perspective, the multiple tanks include inlets to receive cooling fluid and outlets to direct the cooling fluid from each tank;

FIG. 2B is a block diagram of example multiple tanks from a front perspective, each of the multiple tanks include multiple servers;

FIG. 3 is a block diagram of an example inlet directing cooling fluid in a horizontal manner across multiple servers, the cooling fluid is directed to an opposite side of the inlet to an example outlet;

FIG. 4 is a flowchart of an example method to pump cooling fluid into multiple tanks, directing cooling fluid through an inlet to an opposite side on each of the multiple tanks, and expelling cooling fluid from each of the tanks through an outlet on the opposite side of the inlet;

FIG. 5 is a flowchart of an example method to direct cooling fluid in a horizontal manner across multiple servers in each tank;

FIG. 6A is a block diagram of an example cooling system from a front perspective, the cooling system includes multiple inlets to guide cooling fluid into each tank and a heat exchanger to receive expelled cooling fluid to transfer the heat from the cooling fluid prior to pumping the cooling fluid back into each of the multiple tanks; and

FIG. 6B is a block diagram of an example cooling system from a rear perspective, the cooling system includes multiple outlets to expel cooling fluid from each tank.

### DETAILED DESCRIPTION

Cooling systems may use single phase immersion cooling by placing a hardware component into a tank of cooling fluid, such that the hardware is filled and covered by the cooling fluid. In this example, a rack-sized tank may be provided without cooling fluid control. Additionally in this example, the immersion cooling system may create space limitations which may limit the number of hardware components which may be cooled within the cooling systems. Furthermore, the immersion cooling system may be sealed which creates difficulties in accessing the hardware components for servicing.

To address these issues, examples disclosed herein provide an efficient utilization of space in which multiple tiers may consist of multiple tanks. Using multiple tanks across multiple tiers enables each of the multiple tanks to hold multiple servers of various electrical components. This creates a higher power density through enabling multiple tanks across multiple tiers to hold the various electrical components. Further, the cooling structure including the multiple tanks provides a repackaging of the multiple servers into a cartridge form for immersion into a shallow and accessible type of tank.

Additionally, each of the multiple tanks includes a corresponding inlet which may receive the cooling fluid and direct the cooling fluid to an outlet located on an opposite side of each of the multiple tanks. This creates a flow of cooling fluid in a horizontal manner across the multiple servers and electrical components. Creating the flow of cooling fluid in the horizontal manner provides an efficient manner to regulate temperatures among power dense servers and the various electrical components. Additionally, directing the cooling fluid from the inlet to the outlet achieves high power density by using the cooling fluid to regulate the temperature of the electrical components within each of the multiple tanks.

In another example discussed herein, each of the multiple tanks may include an inlet valve on the front side and an outlet valve on the backside of the tank. The inlet valve may control an amount of cooling fluid entering each tank. Controlling the amount of cooling fluid enables the inlet valve to adjust the amount of cooling fluid entering the particular tank without affecting the amount of cooling fluid entering other tanks. The outlet valve may maintain the volume of the cooling fluid within the particular tank by controlling the amount of cooling fluid exiting the particular tank at a given time.

In a further example discussed herein, the mechanical structure of each of the multiple tanks is without a top side. Eliminating the top side, provides an unsealed tank which may provide a more efficient manner to access the multiple servers for servicing the electrical components of the multiple servers within each of the multiple tanks.

In summary, examples disclosed herein provide a cooling structure which achieves high power density by using the cooling fluid to regulate the temperature of the electrical components within each of the multiple tanks. Additionally the examples disclosed herein may control and adjust an amount of the cooling fluid entering and exiting each of the multiple tanks without affecting the flow of the cooling fluid to the other multiple tanks.

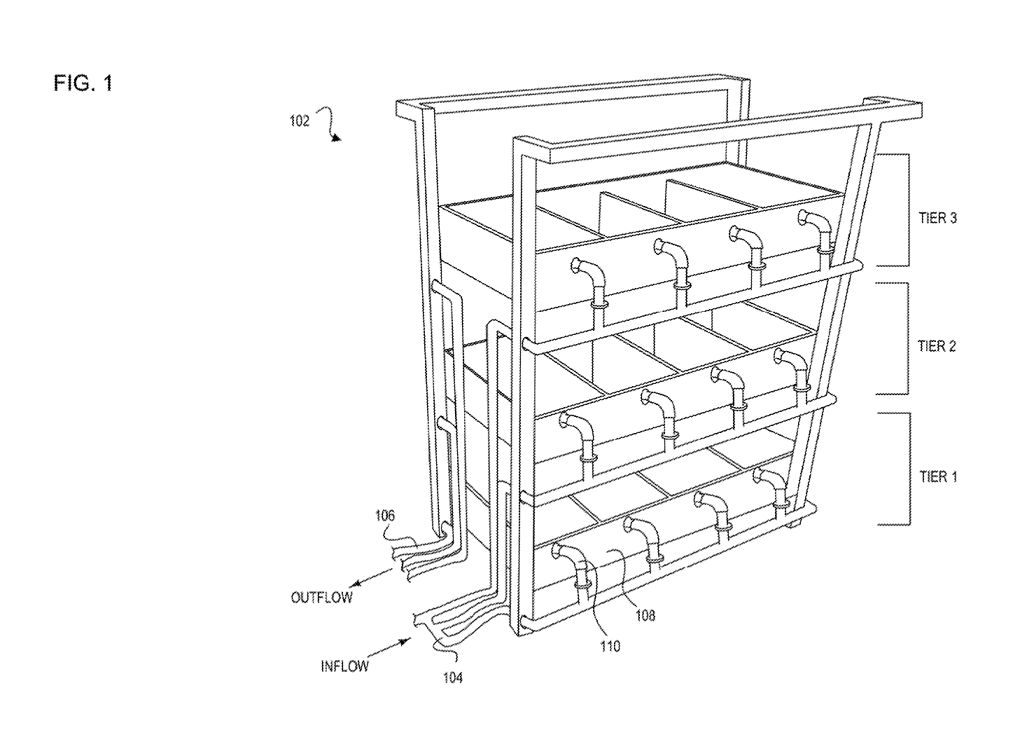

Referring now to the figures, FIG. 1 is a diagram of an example multiple tier (Tier 1, Tier 2, and Tier 3) cooling structure 102 including multiple tanks 108 on each respective tier. The cooling structure 102 includes an inlet system 104 which carries cooling fluid through multiple inlets 110 to enter each of the multiple tanks 108. Each of the multiple inlets 110 are located on a first side of each of the multiple tanks 108 to receive the cooling fluid from the inlet system 104 and direct the cooling fluid to the opposite side of each of the multiple tanks 108. The cooling structure 102 also includes multiple outlets on the backside of the cooling structure to direct an outflow of the cooling fluid in each of the multiple tanks 108 to expel the cooling fluid through an outlet system 106. In one implementation, the expelled cooling fluid enters a heat exchanger to transfer the heat from the cooling fluid so the cooling fluid may be pumped back into each of the multiple tanks 308. The cooling structure 102 provides the capability to regulate temperatures of electronic components within each of the multiple tanks 108. The cooling structure 102 regulates temperatures by enabling the flow of cooling fluid within each of the multiple tanks 108. The cooling structure 102 is type of mechanical structure consisting of multiple tiers (Tier 1, Tier 2, and Tier 3) which serve as shelves within the cooling structure. The shelves may support multiple tanks 108 which in turn may include various electronic components. Although FIG. 1 illustrates the cooling structure 102 as including three tiers, implementations should not be limited as this was done for illustration purposes. For example, the cooling structure 102 may include less than three tiers (e.g., two tiers) or greater than three tiers (e.g., four tiers).

The multiple tanks 108 are each a mechanical storage component which may hold various electronic components. These electronic components may include multiple servers within each of the multiple tanks 108. This implementation is discussed in detail in the next figure. As discussed earlier, each of the multiple tiers supports multiple tanks 108 for cooling the electronic components within each of these tanks. For example, Tier 1 may include four multiple tanks 108 and within each of the four multiple tanks 108 may include electronic equipment. In this manner, each of the multiple tanks 108 serves as a supporting housing for cooling these electronic components. In one implementation, each of the multiple tanks 108 includes four sides and a bottom side while eliminating a top side. This provides easier access to service the various components within each of the multiple tanks 108 without dismantling the other components of the cooling structure 102. Although FIG. 1 illustrates four multiple tanks 108 on each of the multiple tiers, this was done for illustrations purposes and not for limiting implementations. For example, each shelf or tier may include less than four shelves or greater than four shelves.

The inflow system 104 is a type of mechanical structure which carries the cooling fluid to an inlet 110 at each of the multiple tanks 108. In this manner, the inflow system 104 carries the inflow of the cooling fluid within the cooling structure 102 as indicated with the arrow. As such, implementations of the inflow system 106 include a pipe, tube, or other type of mechanical transportation system which enables liquid to flow into the cooling structure 102. In one implementation, the inflow system 104 includes a pump for air enabling the flow of the cooling fluid through the cooling structure 102.

The multiple inlets 110 are mechanical structures which allow the cooling fluid to enter the multiple tanks 108 within the cooling structure 102. In one implementation, the multiple inlets 110 are part of the inflow system 104, each of the multiple inlets 110 enable the cooling fluid to flow from the inflow system 104 into the corresponding tank. In another implementation each of multiple inlets 110 include an inlet valve to control an amount of cooling fluid flowing into a corresponding tank. This implementation is discussed in detail in the next figure.

The outlet system 106 is a type of mechanical structure which enables the cooling fluid to exit each of the multiple tanks 108. In this manner, the outlet system 106 carries the outflow of the cooling fluid from the cooling structure 102 as indicated with the arrow. The outlet system 106 is the mechanical structure which servers to transport the cooling fluid from the cooling structure 102. As such, implementations of the outlet system 106 include a pipe, tube, or other type of mechanical transportation system which enables liquid to flow from the cooling structure 102. In one implementation, the outlet system 106 carries the outflow of the cooling fluid to the beat exchanger. On the backside of the cooling structure 102, the outlet system 106 may include multiple outlets which allow the cooling fluid to flow out of each of the multiple tanks 108. This is illustrated in a later figure. In another implementation, each of the outlets may include an outlet valve which may control the amount of cooling fluid exiting a tank at a given time. This implementation enables the outlet valve to maintain a volume of cooling fluid in the tank at the given time.

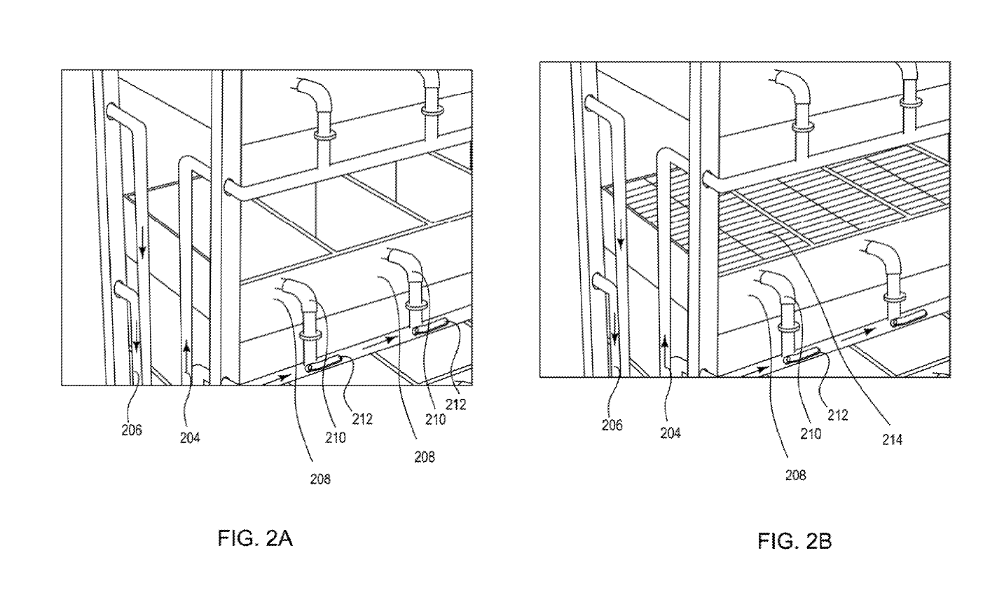

FIGS. 2A-2B are example diagrams of multiple tanks 208 within a cooling structure. The multiple tanks 208 are included without electrical components in FIG. 2A and with electrical components in FIG. 2B. Additionally each of the multiple tanks 208 may include an eliminated top side to the mechanical structure of the tank. Eliminating the top side enables access to service the electrical components within the multiple tanks without dismantling other components of the cooling structure.

FIG. 2A illustrates the multiple tanks 208 on one tier of the cooling structure from a front perspective without electrical components within each of the multiple tanks 208. The multiple tanks 208 include multiple inlets 210, each of the multiple inlets 210 are located on a first side (e.g., front side) of each of the multiple tanks 208. Each of the multiple inlets 210 receive cooling fluid as indicates with the arrows and directs the cooling fluid to an opposite side from the first side (i.e., second side) of each of the multiple tanks 208. The opposite side is on the backside of the cooling structure. Directing the cooling fluid to the opposite side, the flow of the cooling fluid may be directed across the electrical component within each of the multiple tanks 208. Multiple outlets may be located on each of the opposite sides of each of the multiple tanks 208. The multiple outlets may expel the cooling fluid through an outflow system 206. The outflow system 206 may transport the cooling fluid to a heat exchanger. The inflow system 204, the outflow system 206, the multiple tanks 208, and the multiple inlets 210 may be similar in structure and functionality to the inflow system 104, the outflow system 106, the multiple tanks 108, and the multiple inlets 210 as in FIG. 1.

The multiple inlet valves 212 are each located on a first side of each of the multiple tanks 208. In this implementation, the inlet valve 212 is located on the inlet wall of each tank. Each of the multiple inlet valves 212 control an amount of cooling fluid entering a corresponding tank. In one implementation, one of the multiple inlet valves 212 may adjust the amount of cooling fluid flowing to the corresponding tank 208 without affecting the flow of cooling fluid into the other multiple tanks. In this implementation, an outlet valve may be located on the second side of the tank to adjust the amount of cooling fluid exiting the tank based upon the adjustment by the inlet valve 212.

FIG. 2B illustrates the multiple tanks 208 on the one tier of the cooling structure. Each of the multiple tanks 208 may include multiple servers 214 and the associated electrical components. FIG. 2B is from the front perspective of the cooling structure, thus illustrating the flow of the cooling fluid into each of the multiple tanks 208 from the inflow system 204. In one implementation, the multiple servers 214 include multiple microservers for the cooling structure to regulate the temperature. In this implantation, each of the multiple microservers may include a cartridge type of chassis which holds the various electrical components.

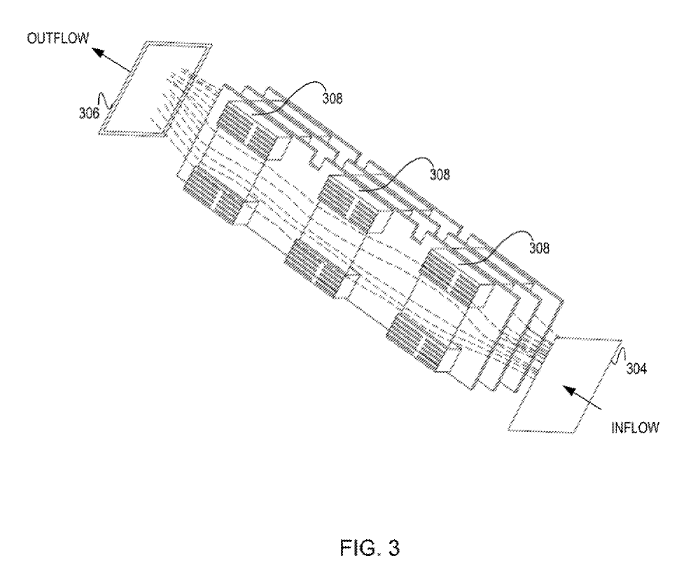

FIG. 3 is a block diagram of an example inlet 304 to receive an inflow of cooling fluid. The inlet 304 directs the cooling fluid in a horizontal manner as indicated with the dashed lines across multiple servers 308. The cooling fluid is directed to an opposite side of the inlet 304 to an outlet 306. At the outlet 306, the cooling fluid is guided to an outflow for exiting a tank. FIG. 3 represents the manner In which cooling fluid flows across each of the multiple servers 308 within a tank. In this implementation, FIG. 3 illustrates a single tank for directing cooling fluid across electrical components housed in that particular tank. Although FIG. 3 illustrates spacing between each of multiple servers 308, this was done for illustration purposes and not for implementation purposes. For example, the amount of spacing may be decreased between each of the multiple servers 308. Additionally, FIG. 3 illustrates nine servers 308 including three across a top layer, three across a middle layer, and three across a bottom layer. This was done for clarification purposes and not for limiting a number of servers and/or a number of layers within each tank, For example, the tank may include multiple layers and/or multiple servers 308. Further, although FIG. 3 represents the single tank for holding multiple servers 308, implementations should not be limited to the single tank. For example, different tanks may be located on either side of the single tank, etc.

The inlet 304 receives an inflow of cooling, fluid and based upon receiving the inflow of cooling fluid, the inlet 304 allows the flow of cooling fluid in the tank. In one implementation, the inlet 304 includes a inlet valve. In this implementation, the inlet valve controls an amount of cooling fluid entering the inlet at a given time. Upon receiving the inflow of cooling fluid, the inlet 304 allows the cooling fluid into the tank, thus directing the cooling fluid in the horizontal manner across each of the multiple servers 308. The horizontal manner describes the flow of the cooling fluid across the multiple servers 308 within the tank.

The outlet 306 receives an outflow of cooling fluid from the tank. In one implementation upon receiving the outflow of cooling fluid, the outlet 306 expels the cooling fluid from the tank. In another implementation, the outlet 306 may include an outlet valve to control the amount of cooling fluid exiting the tank at a given time.

The multiple servers 308 are each a system which may respond to request across a computer network. Each of the multiple servers 308 includes various electrical components which may reach higher temperatures in responding to requests. For each of the multiple servers 308 to continue functionality in handling these requests, the electrical components may be temperature regulated to ensure the components may not overheat, etc. As such, cooling fluid is directed from the inlet 304 to the outlet 306 in the horizontal manner to remove heat from the electrical components. The multiple servers 308 may include microservers, server cartridges, servers, and/or other type of electrical components in which the temperature may be regulated by directing the flow of cooling fluid in the horizontal manner in the tank.

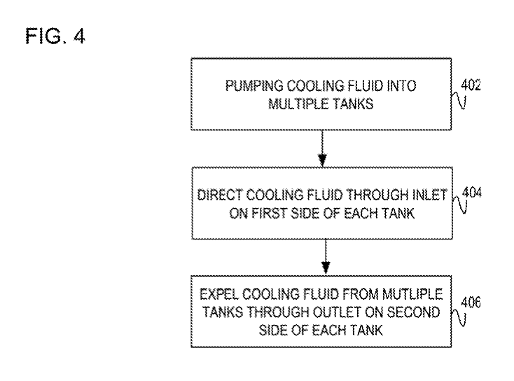

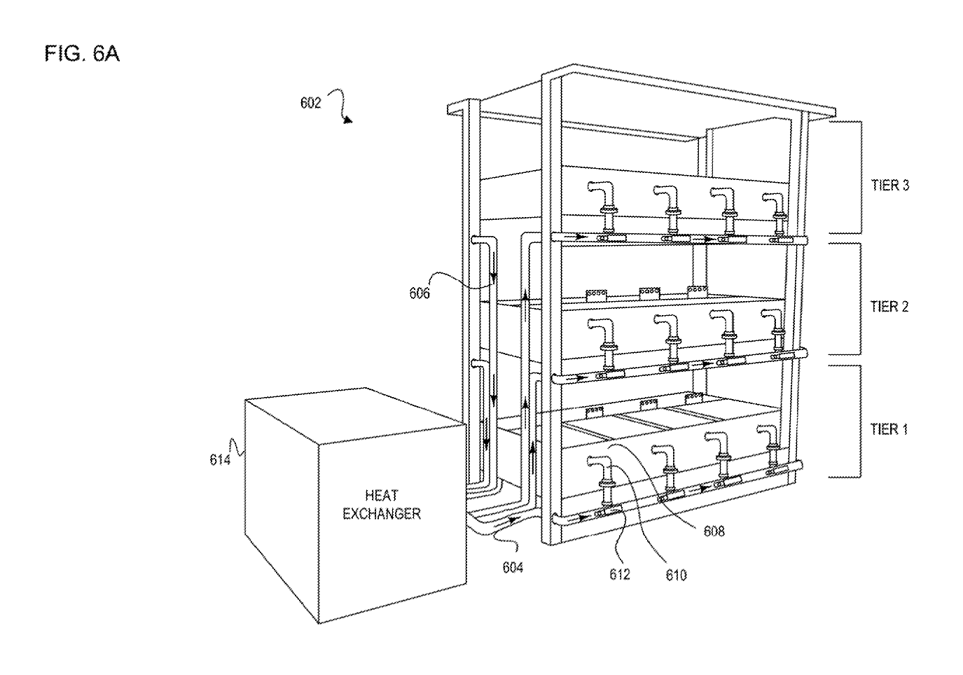

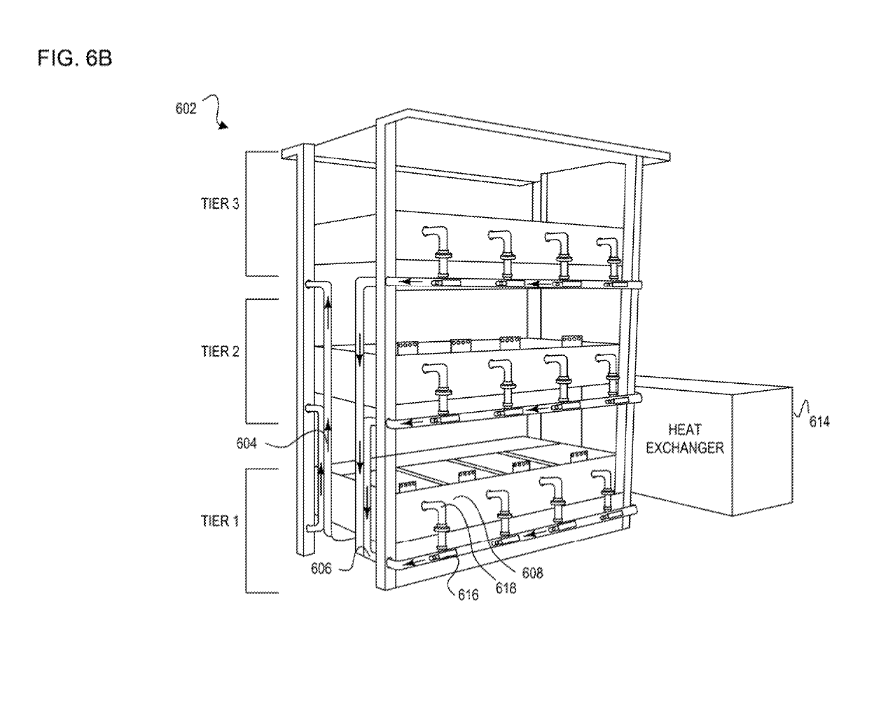

FIG. 4 is a flowchart of an example method to pump cooling fluid into multiple tanks, directing cooling fluid through an inlet to an opposite side on each of the multiple tanks, and expelling cooling fluid from each of the tanks through an outlet on the opposite side of the tank from the inlet. FIG. 4 represents the example method in which the cooling system may operate to regulate temperatures of electrical components within each tank. In discussing FIG. 4, references may be made to the components in FIGS. 1-3 to provide contextual examples. In one implementation, the multiple tier cooling structure 102 as in FIG. 1 includes operations 402-408 for regulating the temperature of various electronic components to prevent overheating. In another implementation of FIG. 4, the cooling system 602 as in FIGS. 6A-6B includes operations 402-408 to prevent overheating of the electrical components within each of the multiple tanks.

At operation 402, the cooling system pumps the cooling fluid into the multiple tanks. In this implementation, the cooling fluid is pumped separately into each tank within the multiple tier structure. A pump may be included, as part of the cooling system which may initiate the cooling system by pumping cooling fluid into each of the multiple tanks. In one implementation, the cooling fluid may be stagnant until the pump operates to pump the cooling fluid into the multiple tanks. In this implementation, the cooling fluid may remain within the pump or may be located throughout the cooling system. The pump enables the cooling fluid to flow within the cooling system. The cooling fluid may enter each of the multiple tanks through an inlet valve located on the first side of each tank as at operation 404. In this manner, each tank includes its own respective inlet to receive the cooling fluid into each tank. The cooling system may include a primary inlet pipe which carries the cooling fluid to the multiple tanks. From the primary inlet pipe, each tank may include its own inlet pipe which allows cooling fluid to flow from the primary inlet pipe into each of the multiple tanks. in another implementation, pumping the cooling fluid into each of the multiple tanks includes immersing the electrical components located within each of the tanks with cooling fluid. This implementation may be discussed in detail in a later figure.

At operation 404, the cooling system may direct the cooling fluid thorough each inlet located on the first side of each tank. Directing the cooling fluid through each inlet on the first side of each tank, the cooling fluid may flow to the opposite side of the tank. In this manner, the cooling fluid may be directed to a side opposite of the first side (e.g., the second side) of each tank. In this implementation, the cooling fluid may be directed across multiple servers in a horizontal manner.

At operation 406, the cooling fluid may exit each of the multiple tanks through the outlet on the second side of each tank. The second side of each tank is located opposite from the first side of the tank. In this manner, the cooling fluid may flow through the inlet on the first side and flow out to the outlet on the opposite side of the tank. Operation 406 may include expelling the cooling fluid from each of the multiple tanks through each outlet. Operation 406 may include expelling the cooling fluid from each outlet located on the opposite side from the inlet. In this manner, the opposite side includes the second side which expels the cooling fluid. Upon expelling the cooling fluid, a heat exchanger may accept the expelled cooling fluid. The heat exchanger may transfer heat from the cooling fluid to another medium within the heat exchanger. This enables the heat from the cooling fluid to transfer to the other medium within the heat exchanger. In this implementation, the cooling fluid may be pumped back into each of the multiple tanks. In this manner, the cooling fluid remains in a continuous loop from each of multiple tanks into the heat exchanger and back through each of the multiple tanks. Looping the cooling fluid through each of the multiple tanks and the heat exchanger, each of the multiple tanks includes a continuous flow of the cooling fluid to regulate the servers within each of the tanks.

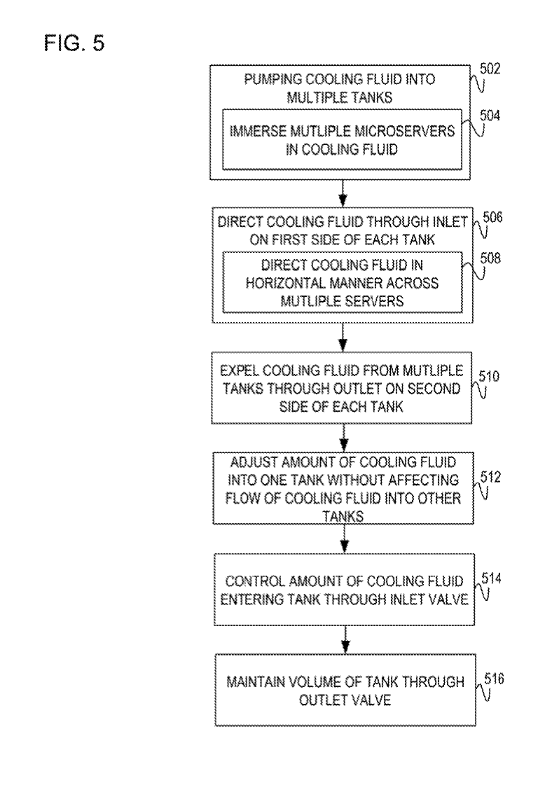

FIG. 5 is a flowchart of an example method to direct cooling fluid in a horizontal manner across multiple servers in each tank. The example method may pump cooling fluid into each of the multiple tanks to immerse multiple servers located in each tank with the cooling fluid. In one implementation, the multiple servers are considered multiple microservers within a cartridge type form. The cooling system may then direct the cooling fluid through an inlet located on a first side of each tank. The cooling fluid may be directed across the multiple servers within each tank by directing the cooling fluid in a horizontal manner to an opposite side of the tank. On the opposite side of the tank includes an outlet for expelling the cooling fluid from the multiple tanks. The cooling system may adjust an amount of the cooling fluid entering each tank through an inlet valve on each of the multiple tanks. This implementation enables the cooling system to control the amount of cooling fluid entering each tank through the inlet valve. Additionally, the volume of the cooling fluid or the amount of the cooling fluid may be maintained by adjusting the amount of the cooling fluid exiting through an exit or outlet valve located on each of the multiple tanks. FIG. 5 represents the example method in which the cooling system may operate to regulate temperatures of electrical components within each tank. In discussing FIG. 5, references may be made to the components in FIGS. 1-3 to provide contextual examples. In one implementation, the multiple tier cooling structure 102 as in FIG. 1 includes operations 502-516 for regulating the temperature of various electronic components to prevent overheating. In another implementation of FIG. 5, the cooling system 602 as in FIGS. 6A-6B includes operations 502-516 to prevent overheating of the electrical components.

At operation 502, the cooling fluid may be pumped into each of the multiple tanks. In this implementation, the cooling fluid enters the inlet on the first side of each tank. In this manner, each tank includes its own respective inlet to receive the cooling fluid into each tank. In one implementation, pumping the cooling fluid into each of the multiple tanks includes immersing the multiple microservers within each of the tanks with the cooling fluid as at operation 504. Operation 502 may be similar in functionality to operation 402 as in FIG. 4.

At operation 504, the cooling system immerses multiple servers located in each of the tanks with the cooling fluid. In one implementation, the multiple servers may be at least partially immersed in the cooling fluid prior to expelling the cooling fluid through each outlet on the opposite side of each tank as at operation 510. In another implementation, each of the servers may be fully immersed in the cooling fluid prior to expelling the cooling fluid as at operation 510. These implementations enable the amount of cooling fluid to remain constant in immersing the servers to regulate the temperature of each of the servers.

At operation 506, the cooling fluid may enter in inlet located on the first side of each tank. In one implementation, the cooling fluid may be directed in horizontal manner across the multiple servers within each of the multiple tanks as at operation 508. Operation 506 may be similar in functionality to operation 404 as in FIG. 4.

At operation 508, the cooling fluid may be directed in a horizontal manner across multiple servers located within each tank. In this implementation, the cooling fluid may enter each tank through an inlet on the first side of the tank and be directed to the opposite side of the tank for expulsion of the cooling fluid through the outlet. In this manner, the cooling fluid may be in a continuous flow to enter each tank and exit on the other side.

At operation 510, the cooling fluid may be expelled through the outlet located on each of the multiple tanks. The outlet is located on the second side of each tank. The second side may be considered the side which is parallel to the first side of the tank or in other words, may be the opposite side to the first side of the tank. The outlet of the tank enables the cooling fluid to exit the tank, while the inlet may allow the cooling fluid to enter the tank. Thus, this enables the continuous flow of cooling fluid. Operation 510 may be similar in functionality to operation 406 as in FIG. 4.

At operation 512, a valve located on the inlet of the tank may adjust an amount of cooling fluid flowing into one of the multiple tanks without affecting a flow of the cooling fluid into the other multiple tanks. In this implementation, the inlet valve may receive a signal indicating to slow the flow of cooling fluid into the tank or increase the amount allowed to enter the tank at a given tank. Each tank may include the inlet valve to adjust the amount of cooling fluid entering each respective tank at a given time. In this manner, the amount of the cooling fluid entering a particular tank may be affected, while the amount of cooling fluid flow into the other tanks may remain unaffected.

At operation 514, the inlet valve may control the amount of cooling fluid entering at least One of the multiple tanks. Each of the multiple tanks includes a respective inlet valve which may control the amount of cooling fluid entering that respective tank. The inlet valve may include a controlling component which may receive a signal whether to increase or decrease the amount of cooling fluid entering the particular tank. In one implementation, if the inlet valve allows more or less cooling fluid to enter the tank at a given time, the outlet valve responds accordingly to maintain a constant amount of fluid in the tank at the given time as at operation 516.

At operation 516, the cooling system may maintain the volume of the cooling fluid into one of the multiple tanks though the exit valve. In this manner, the amount of cooling fluid may be maintained regardless of whether the inlet valve allows more or less cooling fluid to enter the tank. The exit or outlet valve may respond in accordance to the inlet valve depending on whether the inlet valve allows more or less cooling fluid into the tank. For example, if the inlet valve opens to allow an increase in the amount of cooling fluid entering the tank, the outlet or exit valve may allow an increase in the amount of cooling fluid leaving the tank. In this manner, the exit valve may mirror the action of the inlet valve to maintain the volume and/or the amount of cooling fluid may remain constant.

FIGS. 6A-6B are block diagrams illustrating a cooling system 602 from both a front and hack perspective. From the front perspective in FIG. 6A, an inlet system 604 may carry cooling fluid into multiple tanks 608. From the back perspective in FIG. 6B, an outlet system 606 carries the cooling fluid from each of the multiple tanks 608 into a heat exchanger 614.

FIG. 6A is a block diagram of a cooling system 602 from the front perspective. The cooling system 602 includes multiple tiers (Tier 1, Tier 2, and Tier 3) and at each tier includes multiple tanks 608 for immersing multiple servers in a cooling fluid. Each tier (Tier 1, Tier 2, and Tier 3) is a different shelf within the cooling system 602 which holds the multiple tanks 608. The cooling system 602 includes the inlet system 604 with multiple inlets 610 to guide cooling fluid into each tank 608 for cooling the multiple servers within each tank. The cooling system 602 further includes the outlet system 606 to receive expelled cooling fluid from multiple outlets (not illustrated) and guide the expelled cooling fluid to the heat exchanger 614 for transferring heat from the cooling fluid prior to pumping the cooling fluid back into each of the multiple tanks 608. Multiple inlet valves 612 may control an amount of cooling fluid flowing into each of the multiple tanks 608. In one implementation, through providing a different inlet valve at each of the multiple tanks 608, a different amount of cooling fluid may flow into each one of the tanks 608 without affecting the other multiple tanks 608. In a further implementation, a control module may signal to one of the input valves to adjust the amount of cooling fluid flowing into one of the multiple tanks 608. Although FIG. 6A points to single components such as the single tank 608, single inlet 610, and single inlet valve 612, this was done for clarification purposes as the cooling system 602 includes multiple tanks 608, multiple inlets 610, and multiple inlet valves 612. Additionally, FIG. 6A illustrates three tiers (Tier 1, Tier 2, and Tier 3) which was done fur illustration purposes as FIG. 6A may include a fourth tier or less than three tiers, etc. The multiple tanks 608 and multiple inlet valves 612 may be similar in structure and functionality to the multiple tanks 108 and 208 and multiple inlet valves 212 as in FIGS. 1-2.

The inlet system 604 carries the inflow of cooling fluid from the heat exchanger 614 and/or pump into each of the multiple tanks 608. The inlet system 604 carries cooler cooling fluid to each of the multiple tanks 608 as indicated with the arrows pointing into the various tanks. As such, the inlet system 604 may include pipes or other medium capable of carrying cooling fluid to each of the multiple tanks 608.

Upon carrying the cooling fluid from the inlet system 604, the cooling system 602 further includes multiple inlets 610 which allow the cooling fluid into the multiple tanks 608. The multiple inlets 610 may be similar in functionality to inlets 104, 204, and 304 as in FIGS. 1-3.

The outlet system 606 includes multiple outlets as illustrated in FIG. 6B to carry warm cooling fluid from each of the multiple tanks 608. Each of the multiple outlets are located on the side opposite to the inlet side for expelling the cooling fluid. The multiple outlets may be observed on the backside of the cooling system 602 as illustrated in FIG. 6B. The outlet system carries the warm cooling fluid from each of the multiple tanks 608 as indicated through the arrows. As such, the outlet system 606 may include pipes or other medium capable of carrying the warm cooling fluid into the heat exchanger 614.

The heat exchanger 614 is a piece of equipment built for the beat transfer from the expelled cooling fluid. In an implementation, the heat exchanger may include a pump 614 in which to pump the cooling fluid into each of the multiple tanks 608. In this implementation, colder cooling fluid is pumped into each of the multiple tanks 608 where the cooling fluid flows over the multiple servers in each of the multiple tanks 608 and extracts heat from the electrical components within the servers. The warm cooling fluid exits the multiple tanks 608 through the multiple outlets. The outlet system may carry the warm cooling fluid to the heat exchanger 614 where the warm cooling fluid is cooled down and then gets pumped back into each of the multiple tanks 608.

FIG. 6B is a block diagram of the example cooling system 602 as in FIG. 6A from a rear perspective. From the rear perspective, the example cooling system 602 illustrates the multiple outlets 618 for expelling the cooling fluid from each of the multiple tanks 608. The backside of the cooling system 602 further includes multiple outlet valves 616 to control the amount of cooling fluid flowing out of the respective tank. In this implementation, the multiple outlet valves 616 may maintain a volume of the cooling fluid in each of the multiple tanks 608 when the inlet valves 612 adjust the amount of cooling fluid entering the multiple tanks 608.

The multiple outlets 618 allow the cooling fluid to exit the multiple tanks 608 and enter the outlet system 606. The outlet system 606 may proceed to carry the warm cooling fluid to the heat exchanger 614.

In summary, examples disclosed herein provide a cooling structure which achieves high power density by using the cooling fluid to regulate the temperature of the electrical components within each of the multiple tanks. Additionally the examples disclosed herein may control and adjust an amount of the cooling fluid entering and exiting each of the multiple tanks without affecting a flow of the cooling fluid to the other multiple tanks.

1. A multiple tier cooling structure comprising:
multiple tanks, each tank on a respective tier;
multiple inlets, each inlet located on a first side of each tank, to direct a cooling fluid from the first side to a second side; and
multiple outlets, each outlet located on the second site of each tank, to direct an expulsion of the cooling fluid from each tank.

2. The multiple tier cooling structure of claim 1 further comprising:
multiple inlet valves, each inlet valve located, on the first side of each tank, to control an amount of the cooling fluid entering each tank; and
multiple outlet valves, each outlet valve located on the second side of each tank, to maintain a volume of the cooling fluid in each tank.

3. The multiple tier cooling structure of claim 1 wherein each tank holds multiple microservers.

4. The multiple tier cooling structure of claim 1 wherein each tank is without a top side to enable access to multiple servers within each tank.

5. The multiple tier cooling structure of claim 1 wherein a flow of the cooling fluid is adjusted in one of the multiple tanks without affecting the flow of cooling fluid to other multiple tanks.

6. A method cooling multiple servers comprising:
pumping a cooling fluid into multiple tanks, wherein the cooling fluid is pumped separately into each tank in a multiple tier structure;
directing the cooling fluid through each inlet on a first side of each tank; and
expelling the cooling fluid from the multiple tanks through multiple outlets, each outlet located on a second side of each tank.

7. The method of claim 6 wherein directing the cooling fluid through each inlet comprises:
directing the cooling fluid in a horizontal manner across multiple servers in each tank.

8. The method of claim 6 further comprising:
controlling an amount of the cooling fluid entering one of the multiple tanks through an inlet valve; and
maintaining volume of the cooling fluid in one of the multiple tanks through an exit valve.

9. The method of claim 6 wherein pumping cooling fluid into multiple tanks comprises:
immersing multiple microservers within each tank with the cooling fluid.

10. The method of claim 6 further comprising:
adjusting an amount of the cooling fluid flowing into one of the multiple tanks without affecting a flow of the cooling fluid into other multiple tanks.

11. A cooling system comprising:
a tank to immerse multiple servers in a cooling fluid, the tank located above multiple tanks;
an inlet, located on a first side of the tank, to direct the cooling fluid in horizontal manner across the multiple servers; and
an outlet, located on a second side of the tank, to expel the cooling fluid from the tank.

12. The cooling system of claim 11 further comprising:
an inlet valve to control an amount of the cooling fluid flowing into the tank; and
an outlet valve to maintain a volume of the cooling fluid in the tank.

13. The cooling system of claim 11 further comprising:
a heat exchanger to receive the expelled cooling fluid from the outlet on the tank.

14. The cooling system of claim 11 further comprising:
a control module to signal to an input valve to adjust an amount of the cooling fluid flowing into the tank, the adjustment of the cooling fluid does not affect fluid flowing into the multiple tanks.

15. The cooling system of claim 11 wherein each of the multiple tanks includes a different amount of the cooling fluid flowing into each of the multiple tanks.
